(19) United States
(12) Patent Application Publication
(10) Pub. No.: US 2024/0367450 A1
(43) Pub. Date: Nov. 7, 2024

(54) METHOD FOR PRINTING AT LEAST ONE PRECISE LINE BY MEANS OF INKJET PRINTING

(71) Applicant: NOTION SYSTEMS GMBH, Schwetzingen (DE)

(72) Inventors: David HAHN, Schwetzingen (DE); Jan SCHOENEFELD, Schwetzingen (DE)

(21) Appl. No.: 18/683,855

(22) PCT Filed: Aug. 8, 2022
(86) PCT No.: PCT/EP2022/072270

§ 371 Date: Feb. 15, 2024

(30) Foreign Application Priority Data
Aug. 23, 2021 (DE) 10 2021 121 778.4

(51) Int. Cl. B41M 3/00; B41M 5/00

(52) U.S. Cl. CPC B41M 3/008; B41M 5/0047

(57) ABSTRACT

The invention relates to a method for printing at least one precise line (1) by means of inkjet printing. The aim of the invention is to provide a method for printing at least one precise line by means of inkjet printing, which method allows for the printing of a particularly thin, precise line which is uniform over the length and which has no deviation or irregularity in at least one spatial direction and no undesired interruptions. To achieve this aim, the method according to the invention provides for the following as method steps: first, providing a substrate to be printed on, and subsequently printing a first print layer onto the substrate surface, for which purpose at least one print head nozzle and the substrate surface are moved relative to each other along a nozzle path (2), the print head nozzle printing, in each case, a plurality of printing-medium drops (3) in immediate succession along the nozzle path to form a line portion (4), and subsequently leaving clear a printing gap (5) without printing medium on the substrate surface in order to reduce the flowing of printing medium along the line portion. Subsequently, the printing medium of the first print layer is surface-dried, and thereafter at least one additional print layer is printed by moving a print head nozzle and the substrate surface relative to each other along the nozzle path, more particularly the same nozzle path, the print head nozzle printing, in each case, a plurality of printing-medium drops in immediate succession to form an additional line portion (6); the additional line portion printed in the additional print layer being arranged immediately adjacent to or overlapping with an already surface-dried line portion which precedes and/or comes after along the nozzle path and which was printed in a prior print layer.

The invention relates to a method for printing at least one precise line by means of inkjet printing.

Methods for printing on a substrate by way of inkjet printing are known from the prior art in a variety of embodiments and are used for numerous applications—for example, for printing on both rigid and flexible substrates. The method of inkjet printing is particularly suitable for specific applications that require a precise amount of a printing medium to be placed in precisely defined surface areas of the substrate. Such applications relate not only to the printing of colored print media on substrates such as paper, but also, for example, the printing of technical or medical sensor surfaces, reaction surfaces for medical applications, pixel surfaces of displays, such as LCD's, TFT's, OLED displays, or E-paper, or else printing processes in the production and labeling of printed circuit boards.

It is often desirable to print particularly thin, uniform, and optically attractive lines, for which purpose numerous drops of the printing medium are applied one after the other onto the substrate. In order to enable a particularly thin line, the printing medium and/or the substrate surface is preferably selected such that a particularly large contact angle between the surface and the printing medium applied thereto results, or the printing medium and/or substrate selected for this purpose have a particularly large contact angle relative to each other due to the respective material selection. In this case, however, there is the problem that, during the printing of the line, the semi-circular shape of the last-printed drop at the freshly printed end of the line leads to a pump pressure of the liquid printing medium in the line, whereby the already printed printing medium flows along the line, as a result of which local broadenings of the line result due to the large quantity of the printing medium in this region. This leads to an optically perceptible variation in the line width and partially to a three-dimensional deviation or a non-uniformity in at least one spatial direction along the length of the printed line.

According to a solution from the prior art for preventing such a line expansion and for avoiding a deviation or non-uniformity in at least one spatial direction, it is provided for the print head to move more quickly relative to the substrate during the printing and to print the line from individual printing-medium drops arranged next to each other faster than the printed printing medium can flow on the substrate along the line. As a result, however, printing speeds are often necessary which are either not technically feasible at all or, due to the extremely high printing speed, again lead to an unclean printing result and in particular to a lack of uniformity of the printed line, right up to undesired interruptions in the line.

The invention is therefore based upon the object of providing a method for printing at least one precise line by means of inkjet printing, which method enables a printing of a particularly thin, precise line which is uniform over the length and which has no deviation or irregularity in at least one spatial direction and no undesired interruptions.

The method according to the invention for printing at least one precise line by means of inkjet printing provides, as method steps, first, providing a substrate to be printed on, and, subsequently, printing a first print layer on the substrate surface, for which purpose at least one print head nozzle and the substrate surface are moved relative to each other along a nozzle path, and wherein the print head nozzle prints, in each case, several printing-medium drops in immediate succession along the nozzle path to form a line portion, and subsequently leaves clear a printing gap without printing medium on the substrate surface in order to reduce or even largely prevent a flowing of printing medium along the line portion. Subsequently, the printing medium of the first print layer is surface-dried, and, thereafter, at least one additional print layer is printed by moving a print head nozzle and the substrate surface relative to each other along the nozzle path, wherein the print head nozzle prints, in each case, several printing-medium drops in immediate succession to form an additional line portion, and wherein the additional line portion printed in the additional print layer is arranged immediately adjacent to or overlapping with an already surface-dried line portion which precedes and/or comes after along the nozzle path and which was printed in a prior print layer.

The inventor has recognized that by a printing of a line in at least two print layers and by the printing, in each case, of only one line portion in one of the print layers, a strong flow of printing medium along the already printed line can be avoided, whereby the printing of a particularly thin and uniform line is advantageously made possible. In addition, in the method according to the invention, no significant increase in the printing speed is necessary, and therefore a precise drop placement of the printing medium during printing remains possible, which again increases the quality of the printed line optically and/or functionally.

A printing of a precise line according to the invention is an application of printing medium to the substrate surface in such a way that, after completion of the printing process, and in particular after the printing of a last print layer, a sequence of individual printing-medium drops results, said drops being uninterrupted relative to each other and/or having a uniform, smooth, and/or non-corrugated edge relative to the adjacent, unprinted substrate. In this case, a line is preferably formed only from printing-medium drops arranged one after the other along the nozzle path, while the line further preferably comprises no printing-medium drops placed side-by-side. In addition, however, a printing of a line on several print nozzle paths arranged parallel to each other is also conceivable, wherein several printing-medium drops, and in particular up to four printing-medium drops, are then arranged next to each other in the finished printed lines. Furthermore, the line is preferably straight. In addition, however, a curved or angled course of the line relative to the nozzle path is also conceivable, although a better printing result can be produced if the line runs parallel to the nozzle path and, in particular, preferably along or directly on a nozzle path.

In addition to an isolated line, a precise line in the sense of the invention is also understood to mean a line which forms the edge of a printed surface—in particular, since a precise edge of such a surface is often technically necessary and/or is desired by a user. The entire surface can then be formed from individual, adjacently arranged precise lines, or the entire surface can have a precise line at only at least one edge and preferably at all edges.

According to the invention, the printing of the at least one precise line takes place by means of inkjet printing, wherein at least one printing medium is applied dropwise to the substrate surface by means of a print head with at least one print head nozzle and preferably by means of a row of print head nozzles spaced apart from each other, wherein this application preferably takes place completely without contact. The printing-medium drops are ejected successively from at least one print head nozzle, wherein preferably all printing-medium drops are of equal size and/or have a constant volume.

The printing medium, which is applied to the substrate as droplets during printing, can basically be any liquid and serve any purpose. The printing medium can be based, for example, upon an aqueous or non-aqueous solvent and can also comprise any further functional components, e.g., dyes and pigments, but also chemically- and/or biochemically-active substances. Further preferably, the printing medium comprises electrically-conductive substances and/or is provided for forming electrically-conductive structures—in particular, for forming conductor tracks. Particularly preferably, the printing medium is a printing ink or a color pigment solution. Alternatively, however, the printing medium can also be solvent-free and/or can be curable or polymerizable. The printing medium is particularly preferably a UV-curable ink and/or a lacquer—in particular, a solder resist or a conductive lacquer, e.g., a silver-nanoparticle-based lacquer, which further preferably comprises no solvents and is cured by polymerization.

For printing, at least one print head is provided, which can be moved relative to the substrate to be printed so that different positions of the substrate can be printed. The print head can be stationary and the substrate can be moved, or the substrate can be stationary and the print head can be moved. In principle, the print head has at least one print head nozzle for dispensing droplets or a jet of the printing medium, wherein preferably numerous print head nozzles are arranged on the print head in a row and particularly preferably equidistantly relative to one another. In addition, the print head nozzles can also be arranged on the print head in multiple rows—in particular, one behind the other and/or laterally offset from one another in a printing direction.

The substrate surface lying under the region of the print head nozzles during printing and preferably during an individual pass of the print head relative to the substrate surface is referred to as a print head path, while the perpendicular projection of each individual print head nozzle towards the surface of the substrate of a trajectory to be traveled over during the printing process is referred to as a nozzle path. Accordingly, the nozzle path is not necessarily physically mapped as a line on the substrate, but is initially an imaginary trajectory. However, if a print nozzle were to dispense a printing medium continuously over the maximum printing region during a linear movement, the nozzle path would be reproduced on the surface of the substrate as a line by means of the printing medium. In this case, the nozzle path can in principle run both linearly and can have any other non-linear profile. A print head with multiple print head nozzles arranged in a row generates multiple imaginary nozzle paths over the substrate surface during an individual pass of the substrate, with the distance between the nozzle paths corresponding to the native lateral resolution of the print head.

According to the invention, a print head nozzle prints several printing-medium drops in succession along a nozzle path to form a line portion, wherein the distance of the individual, dispensed printing-medium drops on the surface of the substrate is selected according to the invention at least in such a way that the still liquid printing-medium drops touch one another on the surface of the substrate and can run into a common line. Particularly preferably, the distance between successively dispensed printing-medium drops is selected in such a way that a continuous line of constant thickness is printed, for which purpose the distance between the dispensing of individual printing-medium drops from the print head nozzle is preferably less than the diameter—particularly preferably less than 90%, very particularly less than 75%, and in particular preferably less than 50% of the diameter—of the printing-medium drop on the substrate surface.

Further preferably, the print head and in particular a print head nozzle during the printing dispenses each of the individual printing-medium drops at uniform distances along the nozzle path or in relation to the surface of the substrate, so that a particularly uniform line is formed. A line portion is formed from the several printing-medium drops at least partially connecting to one another on the substrate surface, wherein the line portion is preferably formed along a part of a nozzle path and/or a printer head path. Accordingly, a line portion is preferably formed exclusively from several printing-medium drops arranged one after the other, created in a print layer, and/or connected to each other.

The substrate can in principle be formed from any material and can have any shape, wherein the substrate preferably has a planar, printable surface and particularly preferably is formed to be generally flat—in particular, as a plate, sheet, leaf, or film. The substrate can be both rigid and flexible. Furthermore, the substrate can be formed from a fiber material, from wood, from paper, from plastic, and/or from a composite material, and in particular a layered composite material. Particularly preferably, the substrate is a printed circuit board, or rather a PCB, and preferably has conductor tracks at least at a height level relative to the rest of the surface of the substrate, such that the printing takes place on a structured surface—in particular, having at least conductor tracks.

Furthermore, the surface of the substrate to be printed can be untreated. However, the surface of the substrate to be printed is preferably modified, and in particular physically and/or chemically modified, and/or has a surface coating—in particular, in order to ensure a particularly large contact angle with the printing medium, which assists the printing of a particularly thin and precise line in a particularly efficient manner.

According to the invention, the printing takes place in at least two print layers, wherein at least one line portion and preferably several line portions are printed in a first print layer. The first print layer is preferably formed here completely during a pass of the print head or in a print head path. Furthermore, in the first print layer, the print head preferably continuously passes along a nozzle path through all positions of the substrate surface that are to be printed in this print layer. With the printing of several lines—in particular, parallel to one another and at the same time spaced apart from each other—on the substrate surface, in principle both a printing first of all print layers of a single line can be printed, as well as a complete printing of the first print layer of all lines, followed by the printing of the additional print layer or print layers of all lines. Likewise preferably, the printing of all print layers is carried out identically to each other, and in particular at the same printing speed and/or with printing parameters identical to each other. Although a printing of the precise line in any number of print layers is conceivable, a printing in a maximum of three print layers and in particular in exactly two print layers is preferred, since this enables a particularly rapid printing.

According to the invention, the printing medium of the first print layer is surface-dried on the substrate surface before the second print layer is printed, and such a surface drying is preferably carried out between the printing of all print layers. The surface drying is understood to mean an evaporation of the solvent and/or a setting, polymerization, and/or a solidification of at least one substance of the printing medium and in particular of the entire printing medium, so that at least the additional printing medium of the subsequent print layer, which is printed onto the surface-dried printing medium, no longer runs with the surface-dried printing medium, and/or so that liquid printing medium of the subsequent print layer with the surface-dried printing medium substantially forms the same contact angle as completely dried printing medium. Curing or surface-hardening is accordingly also understood as surface-drying. The proportion of the polymerized and/or cured printing medium after surface drying is preferably at least 30%, particularly preferably at least 50%, very particularly preferably at least 80%, and particularly preferably at least 90%. Furthermore, the viscosity of the surface of the printing medium or of the entire printing medium after the surface drying or the surface hardening is so high that a flowing is essentially no longer possible. Accordingly, the method step of surface drying or surface hardening essentially serves for dimensional consolidation of the freshly-printed printing medium. The surface drying can be carried out here by leaving the solvent of the printing medium to dry or by evaporating it, or, technically assisted, for example, by heating, an ambient air circulation, a gas or air jet, or by irradiation—in particular, with UV or IR light. A curing or polymerization can also take place by a waiting duration and/or, technically assisted, for example, by heating, an ambient air circulation, a gas or air jet, or by irradiation—in particular, with UV or IR light.

According to the invention, a printing gap without printing medium is left clear at least in the first print layer, and preferably in every print layer apart from the last print layer at least after one line portion, and preferably at least between two line portions. Very particularly preferably, a printing gap is left clear between all line portions of a line, and in particular during the printing of the first print layer. For generating the printing gap, at least one printing-medium drop is preferably omitted during printing, so that a portion of the substrate surface is not printed with the printing medium and remains free in this print layer. Here, a printing gap preferably continues the line to be printed, only without a printing of printing medium.

Lastly, in order to form the precise line in the method according to the invention, it is provided that an additional line portion be printed in the additional print layer, in any additional print layer, and/or at least in the last print layer. In this case, the printing of the additional line portion is arranged along the nozzle path or, spatially, immediately adjacent to or overlapping with a line portion which precedes and/or comes after along the nozzle path and which was printed in a prior print layer, so that the line portion printed in a prior print layer and the further line portion form at least one, longer, uninterrupted line portion, and preferably all line portions form the entire uninterrupted line.

An immediately adjacent arrangement of the further line portion to a previously printed line portion is understood in particular to mean an arrangement of the first printing-medium drop at the end of the previously printed line portion, in which an overlap of the line end and of the newly printed printing drop is large enough that the contact region of both line portions is not visible, and/or that the two line portions form a visually uninterrupted line, and/or that both adjacently arranged end regions of both line portions have an identical line width. For this purpose, an overlap of the end of the previously printed line and of the first printing-medium drop of the further line portion is preferably provided between 10% and 90%, particularly preferably between 25% and 75%, and very particularly preferably between 40% and 60% of the diameter of a printing-medium drop.

By contrast, an overlapping arrangement of the previously printed line portion and of a further line portion is understood to mean an arrangement in which at least the start of a further printed line portion—in particular, the semi-circular part of the start—is placed completely on the at least surface-dried end of an already printed line portion. This results in the advantage that the liquid printing medium does not come into contact with the substrate surface, but, rather, with the surface of the surface-dried printing medium, and thus forms a different contact angle than with the substrate surface, which can lead to a reduction in the pump pressure and thus in the printing medium flow in the direction of the beginning of the still liquid line portion and/or to an optical improvement of the printing result. Preferably, there is an overlap of a surface-dried end of a previously printed line portion and of a straight, printed, additional line portion by at least one printing-medium drop or by its diameter.

An advantageous embodiment of the method according to the invention for printing at least one precise line provides that each printing-medium drop be printed in a field of a (virtual) grid of printing positions in rows and columns, wherein the one or more line portions printed in the first print layer and/or the following printing gaps extend, in each case, over several fields of a row arranged one after the other, and preferably all printing-medium drops printed in a print layer are connected to form a line portion, and/or all line portions of all print layers are connected to form a line.

In principle, the line portions and/or the printing gaps can each be of any length, wherein, however, the effect of the printing medium flowing along the line portion and the associated increase of the waviness are intensified with increasing length of the line portion. Accordingly, it is advantageous if each printed line portion and/or each printing gap are between 1 and 100, preferably between 2 and 50, particularly preferably between 2 and 10, and very particularly preferably between 2 and 5 fields long or are formed from a corresponding number of printing-medium drops. All line portions and/or all printing gaps can each be of identical length or can each be of an individual length. Preferably, the line portions of a print layer are all of the same length and/or, likewise preferably, all printing gaps of a print layer are of the same length. Particularly preferably, the line portions and the printing gaps of a print layer are not of equal length, and, very particularly preferably, the line portions of a print layer, and in particular at least the first print layer, are longer than the printing gaps of this print layer.

In particular, it is advantageous if each printed line portion is between 1 and 100, preferably between 2 and 50, particularly preferably between 2 and 10, very particularly preferably between 2 and 5, and in particular preferably between 3 and 5 fields long, or is formed from a corresponding number of printing-medium drops, and/or if each printing gap is between 2 and 100, preferably between 2 and 50, particularly preferably between 2 and 10, very particularly preferably between 2 and 5, and in particular preferably between 3 and 5 fields long, or is formed from a corresponding number of printing-medium drops, whereby a flowing of the printing medium along the line and an associated widening or waviness of the line can be particularly well avoided.

In principle, the length ratio between the line portions and the printing gaps of a print layer can be selected as desired, wherein it is preferred, however, that the line portions of the first print layer be the same length as the printing gaps of this print layer and/or that the line portions of the last print layer be longer than the printing gaps of this print layer. In particular, it is preferred here that the line portions of the first print layer be between 3 and 5 printing-medium drops long and/or the printing gaps be between 2 and 3 printing gaps long. Furthermore, it is preferred that the line portions of the last print layer be between 3 and 6 printing-medium drops long. Furthermore, it is preferred that the printing gaps of the last print layer be shorter than the printing gaps of the first print layer and/or that the line portions of the first print layer be shorter than the line portions of the last print layer.

In an advantageous embodiment of the method according to the invention for printing at least one precise line, the complete printing of the precise line takes place in two print layers. Alternatively or additionally, the additional line portions of the last print layer—in particular, a second print layer—completely fill the remaining printing gaps between previously printed line portions. By way of a corresponding printing, a precise line can be printed particularly quickly and with the smallest possible number of passes of the print head.

According to a preferred development of the method according to the invention for printing at least one precise line, the additional line portion or the additional line portions are each printed overlapping with the line portion which precedes and which comes after along the nozzle path, and which was printed in a prior print layer, so that both ends of the additional line portion meet the previously printed and already surface-dried printing medium. It is particularly preferred that the overlap between a previously printed line portion and a further line portion of an additional print layer be between 1 and 3, particularly preferably between 1 and 2, and very particularly preferably exactly 1 field or a corresponding number of printing-medium drops.

Although, basically, only a part of the print and/or a part of a line can be formed from individually printed line portions, it is preferred that the complete printing of a precise line and particularly preferably of the entire surface of the substrate take place in several print layers of first and additional line portions.

In addition, it is preferred that the printing in all print layers and/or all line portions take place by means of the same printing medium—in particular, a curable lacquer—for which purpose precisely one print head is very particularly preferably used in each print layer. Particularly preferably, all printing-medium drops of a print layer are printed along a nozzle path by means of the same print head nozzle, and/or the line portions of a nozzle path are each printed with a different print head nozzle in each print layer.

An exemplary embodiment of the method according to the invention is explained in greater detail below with reference to the drawings. In the figures:

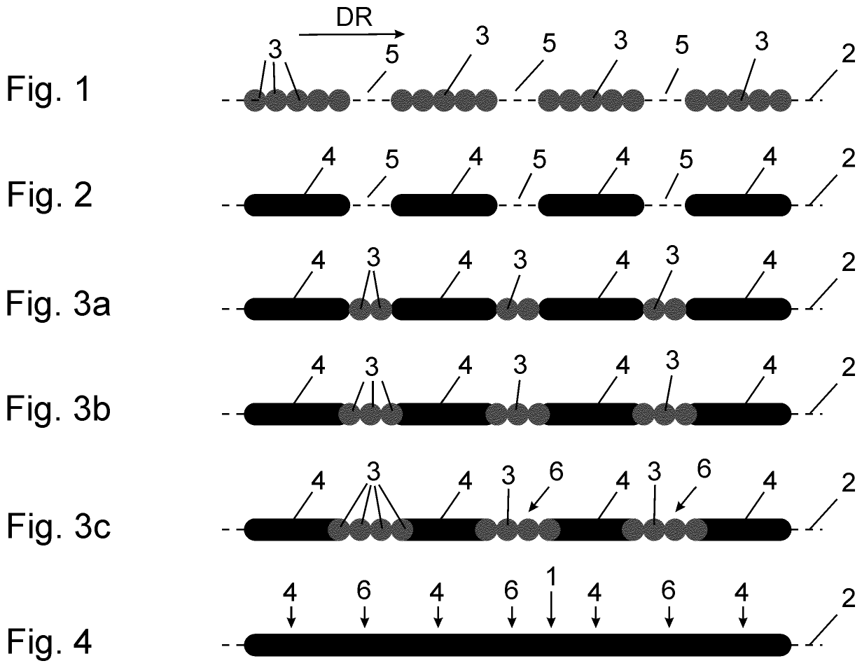

FIG. 1 shows a schematic view of several line portions printed on a substrate surface of liquid printing-medium drops,

FIG. 2 shows a schematic view of the line portions shown in FIG. 1 after the printing medium has surface-dried,

FIG. 3a shows a schematic view of several liquid printing-medium drops printed adjacently to the surface-dried line portions of FIG. 2,

FIG. 3b shows a schematic view of several printed liquid printing-medium drops overlapping the surface-dried line portions of FIG. 2,

FIG. 3c shows a schematic view of several printed liquid printing-medium drops completely overlapping the surface-dried line portions of FIG. 2, and

FIG. 4 shows a schematic view of a printed precise line.

In an embodiment of the method for printing a precise, thin, uniform line 1 without a deviation or non-uniformity in at least one spatial direction, a paper is first provided as a substrate for the inkjet printing and has, on its surface, a coating which ensures a large contact angle between the substrate and the printing ink. Alternatively, the surface of a printed circuit board can also be printed, wherein the printing ink is then particularly preferably a solder resist.

Subsequently, the substrate is moved relative to a print head having at least one print head nozzle along a linear nozzle path 2, so that the print head nozzle is moved over every printable position on the substrate surface during a single pass, and a relative movement of the print head along a printing direction DR results. During this relative movement along the nozzle path 2, the print head dispenses through the printing nozzle regularly and at predetermined positions a single printing-ink drop 3 (see FIG. 1), wherein all printing-ink drops 3 have a volume that is identical to each other. The printing of these printing-ink drops 3 forms the first print layer.

The respective position of the dispensing of a printing-ink drop 3 is selected here in such a way that several printing-ink drops 3 first pass directly next to each other onto the substrate surface and form a smooth line portion 4 due to the flowing on the substrate surface, wherein a printing gap 5 is left clear after a predetermined number of printing-ink drops 3—in this example, precisely after five printing-ink drops 3 in each case—which printing gap—in this example—has a length along the nozzle path 2 of two printing-ink drops 3.

The printing-ink drops 3 of the first print layer that are positioned directly next to each other and in liquid form reach the substrate surface each form a line portion 4 which already has a uniform width (see FIG. 2). The printing ink is subsequently left to surface dry, wherein the solvent contained in the printing ink is left to evaporate, or the printing ink—in particular, a solder resist-largely sets or polymerizes.

Subsequently, the print head is again displaced to the beginning of the nozzle path 2 already traveled over in the first print layer, and a second print layer is printed, which preferably takes place with a print head nozzle different from the one used for the printing of the first print layer. In this case, however, a printing-ink drop 3 is released only in the region of positions which were not printed during the printing the first print layer and where a printing gap 5 of the first print layer was accordingly provided. The printing-ink drops 3 printed immediately adjacently to each other in the additional print layer also connect to one another again to form additional line portions 6.

In this case, a first variant of the printing of the second print layer provides that the first and last printing-ink drops 3 of an additional line portion 6 of the second print layer be each positioned exactly next to the end of the line portion 4 printed in the prior print layer, so that no deliberate overlap of the two line portions 4, 6 occurs, but at the same time the printing ink runs such that, at the positions where the two line portions 4, 6 of the two print layers abut each other, the line 1 has a constant thickness (see FIG. 3a). An overlap is avoided here—in particular, insofar as it is not absolutely necessary for an interference-free connection of the line portions 4, 6 to each other.

Furthermore, a second variant of the printing of the second print layer provides that the first and last printing-ink drops 3 of an additional line portion 6 of the second print layer be each positioned on the corresponding end of the line portion 4 printed in the prior print layer, so that there is an overlap of the two line portions 4, 6 by about half of the printing-ink drop width, wherein the line 1 at the same time has a constant thickness as before at the positions where the two line portions 4, 6 of the two print layers abut each other (see FIG. 3b).

By contrast, a third variant of the printing of the second print layer provides that the first and last printing-ink drops 3 of an additional line portion 6 of the second print layer each completely cover exactly the end of the line portion 4 printed in the prior print layer (see FIG. 3c), whereby a particularly good connection is created, and, in addition, the newly printed, still liquid printing-ink drop 3 comes into contact with already dried printing ink and only to a small extent with the surface of the substrate, whereby a subsequent flow of printing ink along the newly printed line portion 6 is prevented in a simple manner.

Lastly, the line portions 6 printed in the second print layer then also dry completely, and a particularly precise, thin, uniform line 1 is obtained without a deviation or a non-uniformity in at least one spatial direction in which no connection regions are visible between the line portions 4 printed in the first print layer and the line portions 6 printed in the second print layer (see FIG. 4).

### LIST OF REFERENCE SIGNS

1 Line
2 Nozzle path
3 Printing-medium drop
4 Line portion
5 Printing gap
6 Additional line portion
DR Printing direction

1. A method for printing at least one precise line by inkjet printing, comprising the steps of:
providing a substrate having a substrate surface to be printed on;
printing a first print layer onto the substrate surface, for which purpose at least one print head nozzle and the substrate surface are moved relative to each other along a nozzle path, and wherein
the at least one print head nozzle prints several printing-medium drops in immediate succession along the nozzle path to form a line portion and subsequently leaves clear a printing gap without a printing medium on the substrate surface in order to reduce a flowing of the printing medium along the line portion;
surface-drying the printing medium of the first print layer;
printing at least one additional print layer by moving the at least one print head nozzle and the substrate surface relative to each other along the nozzle path, wherein
the at least one print head nozzle prints several printing-medium drops in immediate succession to form an additional line portion, wherein
the additional line portion printed in the additional print layer is arranged immediately adjacent to or overlapping with the line portion which precedes and/or comes after along the nozzle path and which was printed in a prior print layer.

2. The method for printing at least one precise line according to claim 1, wherein
each printing-medium drop is printed in a field of a grid of printing positions in rows and columns, wherein
the line portion printed in the first print layer and/or the following printing gap each extend over several fields of a row arranged one after the other, and
all the printing-medium drops printed in a single print layer are connected to form a line portion, and/or all the line portions of all print layers are connected to form a line.

3. The method for printing at least one precise line according to claim 1, wherein each printed line portion and/or each printing gap is/are from 1 to 100 fields long or is/are formed from a corresponding number of the printing-medium drops.

4. The method for printing at least one precise line according to claim 1, wherein
each printed line portion is from 1 to 100 fields long or is formed from a corresponding number of the printing-medium drops, and/or
each printing gap is from 2 to 100 fields long or is formed from a corresponding number of the printing-medium drops.

5. The method for printing at least one precise line according to claim 1, wherein
complete printing of the precise line takes place in two print layers, and/or
the additional line portions of a last print layer
at least completely fill remaining printing gaps between previously printed line portions.

6. The method for printing at least one precise line according to claim 1, wherein the additional line portion(s) are each printed overlapping with the line portion which precedes and which comes after along the nozzle path and which was printed in a prior print layer, so that both ends of the additional line portion meet the previously printed and already surface-dried printing medium.

7. The method for printing at least one precise line according to claim 1, wherein an overlap between a previously printed line portion and an additional line portion of an additional print layer is from 1 to 3 fields or a corresponding number of the printing-medium drops.

8. The method for printing at least one precise line according to claim 1, wherein the complete printing of a precise line takes place in several print layers of first and additional line portions.

9. The method for printing at least one precise line according to claim 1, wherein the printing takes place in all print layers and/or all line portions by use of the same printing medium.

10. The method for printing at least one precise line according to claim 1, wherein all the printing-medium drops of a print layer are printed along a nozzle path by the same print head nozzle, and/or in that the line portions of a nozzle path are each printed with a different print head nozzle in each print layer.
